(19) United States
(12) Patent Application Publication
(10) Pub. No.: US 2009/0262719 A1
(43) Pub. Date: Oct. 22, 2009

(54) Apparatuses and methods for beamforming in a multiple input multiple output (MIMO) wireless communication system based on hybrid division duplex

(75) Inventors: Sei-Joon Shim, Seoul (KR); Dong-Hee Kang, Seoul (KR); Tai-Suk Kim, Seoul (KR)

Correspondence Address: DOCKET CLERK, P.O. DRAWER 800889, DALLAS, TX, 75380, US

(73) Assignee: Samsung Electronics Co., Ltd., Suwon-si (KR)

(21) Appl. No.: 12/386,300

(22) Filed: Apr. 16, 2009

(30) Foreign Application Priority Data
Apr. 16, 2008 (KR) 10-2008-0035006

(51) Int. Cl. H04B 7/216; H03D 1/00

(52) U.S. Cl. 370/342; 375/340

(57) ABSTRACT

Beamforming in a Multiple Input Multiple Output (MIMO) wireless communication system is provided. An apparatus includes an estimator for estimating a channel matrix of at least one terminal compliant with a Time Division Duplex (TDD) scheme; a processor for confirming information indicative of a channel matrix fed back from at least one terminal compliant with a Frequency Division Duplex (FDD) scheme; and a controller for determining precoding vectors or terminals to be connected in a spatial multiple access manner, using the channel matrix of the at least one terminal compliant with the TDD scheme and a principal vector of the at least one terminal compliant with the FDD scheme.

### CROSS-REFERENCE TO RELATED APPLICATION(S) AND CLAIM OF PRIORITY

The present application claims the benefit under 35 U.S.C. §119(a) to a Korean patent application filed in the Korean Intellectual Property Office on Apr. 16, 2008 and assigned Serial No. 10-2008-0035006, the entire disclosure of which is hereby incorporated by reference.

### TECHNICAL FIELD OF THE INVENTION

The present invention relates generally to a Multiple Input Multiple Output (MIMO) wireless communication system. More particularly, the present invention relates to apparatuses and methods for beamforming in a MIMO wireless communication system based on a Hybrid Division Duplex (HDD).

### BACKGROUND OF THE INVENTION

In response to increasing demands for high-speed and high-quality data transmission, a Multiple Input Multiple Output technique using a plurality of transmit antennas and receive antennas is drawing great attention as one of solutions to meet those demands. The MIMO technique carries out communication using a plurality of channels via the multiple antennas, to thus drastically enhance a channel capacity, compared to a single-antenna system. For example, when transmitter and receiver each include M-ary transmit antennas and M-ary receive antennas, channels between the antennas are independent of each other, and a bandwidth and a total transmit power are fixed, an average channel capacity increases by M times the single antenna system.

The MIMO technique may be divided into a Single User (SU) MIMO and a Multiple User (MU) MIMO. The SU MIMO enables a pair of the transmitter and the receive antennas to conduct one-to-one communication by occupying all of the channels by means of the multiple antennas. The MU MIMO concerns one-to-many communication between the transmitter and the receivers by splitting the plurality of the channels by virtue of the multiple antennas.

When one base station and a plurality of terminals communicate with each other at the same time according to the MU MIMO technique, transmit signals and receive signals of the terminals are mixed in the channels. The base station and the terminals may distinguish the signal of the individual terminals by preceding the transmit signal and combining the receive signals. Herein, the precoding process multiplies the transmit signal by a transmit beamforming vector; that is, by a precoding vector, and the combining process multiplies the receive signal by a receive beamforming vector; that is, by a combining vector. To do so, the base station needs to determine the precoding vector and the combining vector of each terminal. The precoding vector and the combining vector should meet a condition of not causing interference between the terminals after the combining at the terminal. In other words, to realize the effective spatial multiple access communication in the MU MIMO wireless communication system, what is needed is a method for determining an optimum precoding vector and an optimum combining vector.

### SUMMARY OF THE INVENTION

To address the above-discussed deficiencies of the prior art, it is a primary aspect of the present invention to address at least the above mentioned problems and/or disadvantages and to provide at least the advantages described below. Accordingly, an aspect of the present invention is to provide an apparatus and a method for generating a precoding vector and a combining vector in a MIMO wireless communication system.

Another aspect of the present invention is to provide an apparatus and a method for generating a precoding vector and a combining vector applicable to a Hybrid Division Duplex (HDD) scheme in a MIMO wireless communication system.

Yet another aspect of the present invention is to provide an apparatus and a method for generating a precoding vector and a combining vector using full channel information of a terminal compliant with a Time Division Duplex (TDD) scheme and limited channel information of a terminal compliant with a Frequency Division Duplex (FDD) scheme in a MIMO wireless communication system.

According to one aspect of the present invention, an apparatus for a base station in a MIMO wireless communication system includes an estimator for estimating a channel matrix of at least one terminal compliant with a TDD scheme; a processor for confirming information indicative of a channel matrix fed back from at least one terminal compliant with a FDD scheme; and a controller for determining precoding vectors for terminals to be connected in a spatial multiple access manner, using the channel matrix of the at least one terminal compliant with the TDD scheme and a principal vector of the at least one terminal compliant with the FDD scheme.

According to another aspect of the present invention, an apparatus for a terminal in a MIMO wireless communication system includes a processor for confirming precoding vector information from a control signal received from a base station; a calculator for determining a combining vector using the precoding vector; and a combiner for extracting a signal transmitted in at least one allocated stream, by multiplying signals received via a plurality of receive antennas by a Hermitian matrix of the combining vector.

According to yet another aspect of the present invention, a method of operating a base station in a MIMO wireless communication system includes estimating a channel matrix of at least one terminal compliant with a TDD scheme; confirming information indicative of a channel matrix fed back from at least one terminal compliant with a FDD scheme; and determining precoding vectors for terminals to be connected in a spatial multiple access manner, using the channel matrix of the at least one terminal compliant with the TDD scheme and a principal vector of the at least one terminal compliant with the FDD scheme.

According to still another aspect of the present invention, a method for operating a terminal in a MIMO wireless communication system includes confirming precoding vector information from a control signal received from a base station; determining a combining vector using the precoding vector; and extracting a signal transmitted in at least one allocated stream, by multiplying signals received via a plurality of receive antennas by a Hermitian matrix of the combining vector.

Other aspects, advantages, and salient features of the invention will become apparent to those skilled in the art from the following detailed description, which, taken in conjunction with the annexed drawings, discloses exemplary embodiments of the invention.

Before undertaking the DETAILED DESCRIPTION OF THE INVENTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates a frame structure of a Multiple Input Multiple Output (MIMO) wireless communication system according to an exemplary embodiment of the present invention;

FIG. 2 illustrates a cell coverage division in the MIMO wireless communication system according to an exemplary embodiment of the present invention;

FIG. 3 illustrates a communication model in the MIMO wireless communication system according to an exemplary embodiment of the present invention;

FIG. 4 illustrates a base station in the MIMO wireless communication system according to an exemplary embodiment of the present invention;

FIG. 5 illustrates a terminal in the MIMO wireless communication system according to an exemplary embodiment of the present invention;

FIG. 6 illustrates operations of the base station in the MIMO wireless communication system according to an exemplary embodiment of the present invention;

FIG. 7 illustrates operations of the terminal in a zone A in the MIMO wireless communication system according to an exemplary embodiment of the present invention;

FIG. 8 illustrates operations of the terminal in a zone B in the MIMO wireless communication system according to an exemplary embodiment of the present invention; and

FIG. 9 illustrates a performance of the MIMO wireless communication system according to an exemplary embodiment of the present invention.

Throughout the drawings, like reference numerals will be understood to refer to like parts, components and structures.

### DETAILED DESCRIPTION OF THE INVENTION

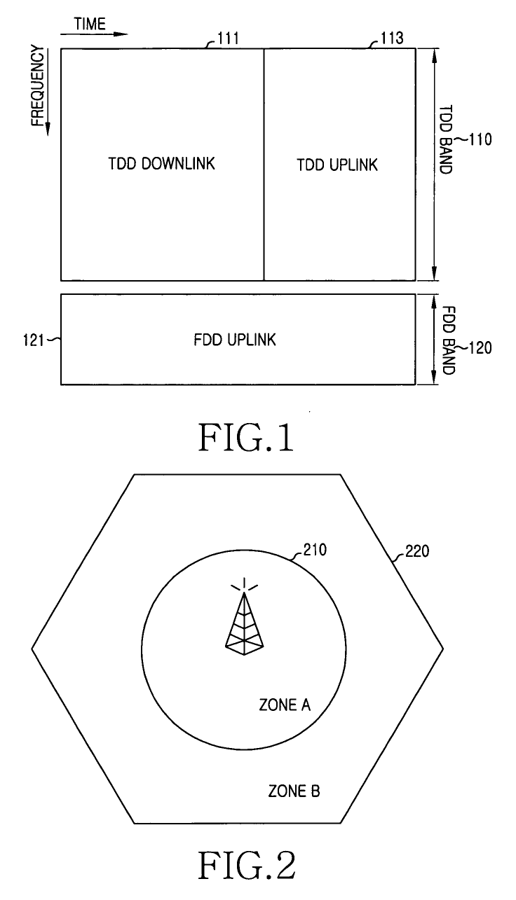

FIGS. 1 through 9, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged wireless communications system.

It will be understood that the singular forms “a,” “an,” and “the” include plural referents unless the context clearly dictates otherwise. Thus, for example, reference to “a component surface” includes reference to one or more of such surfaces.

Use of the term “substantially” is meant to denote that the recited characteristic, parameter, or value need not be achieved exactly, but that deviations or variations, including for example, tolerances, measurement error, measurement accuracy limitations and other factors known to skill in the art, may occur in amounts that do not preclude the effect the characteristic was intended to provide.

Exemplary embodiments of the present invention provide a technique for generating precoding vectors and combining vectors for a spatial multiple access in a MIMO wireless communication system.

A system under the consideration in an exemplary embodiment of the present invention is explained first.

The system considered herein complies with an HDD scheme. A frame structure of the HDD system is illustrated in FIG. 1. FIG. 1 illustrates a frame structure of a MIMO wireless communication system according to an exemplary embodiment of the present invention. In FIG. 1, a use frequency band of the system is divided largely into a TDD band 110 and a FDD 120. The TDD band 110 is subdivided to a TDD downlink zone 111 and a TDD uplink zone 113. The FDD band 120 includes an FDD uplink zone 121. A base station transmits signals to terminals over the TDD downlink zone 111. The terminals transmit a signal to the base station via the TDD uplink zone 113 and the FDD uplink zone 121.

The terminals conduct the uplink communication in one of the TDD uplink zone 113 and the FDD uplink zone 121. A location of the terminal determines which zone is used by the terminal. More specifically, a cell illustrated in FIG. 2 is split to a zone A 210 and a zone B 220, a terminal traveling in the zone A 210 uses the TDD uplink zone 113, and a terminal traveling in the zone B 220 uses the FDD uplink zone 121. Hence, interference to the neighbor cell is mitigated.

As referenced herein above, in the communication based on the HDD, the TDD band 110 is used for both of the uplink communication and the uplink communication. By virtue of channel reciprocity of the channel according to the TDD, the base station may acquire the downlink channel of the terminal in the zone A 210 by estimating the uplink channel of the terminal in the zone A 210. However, since the FDD band 120 is used solely for the uplink communication, the base station itself cannot acquire the downlink channel of the terminal in the zone B 220. Instead, the base station may identify the downlink channel through the feedback from the terminal. That is, the base station has full downlink channel information of the terminal traveling in the zone A 210 and limited downlink channel information of the terminal traveling in the zone B 220.

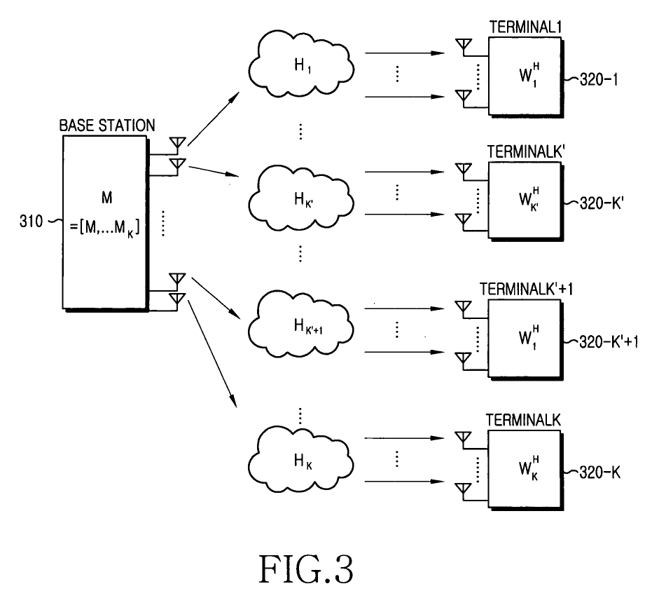

FIG. 3 illustrates a system model in which a base station 310 and K-ary terminals 320-1 to 320-K communicate with each other in the spatial multiple access scheme. The base station 310 multiplies transmit signals destined for the terminals 320-1 to 320-K by preceding vectors respectively, sums up the transmit signals multiplied by the preceding vectors, and then transmits the summed signal via antennas. The summed signal is received at the terminals 320-1 to 320-K over channels of the terminals 320-1 to 320-K. The terminals 320-1 to 320-K each acquire the transmit signal by multiplying the receive signal by their combining vector. In so doing, a downlink signal model received at the terminal k 320-k is expressed as Equation 1:

$${y}_{k} = {H}_{k} {m}_{k} {s}_{k} + {H}_{k} {\sum }_{l = 1 , l \neq k}^{K} {m}_{l} {s}_{l} + {n}_{k} \qquad [ Eqn . 1 ]$$

In Equation 1, yₖ denotes a receive signal vector of the terminal k, Hₖ denotes a channel matrix of the terminal k, mₖ denotes a precoding vector of the terminal k, sₖ denotes a transmit signal of the terminal k, K denotes the number of terminals to be connected in the spatial multiple access manner, and nₖ denotes noise affecting the terminal k.

Using the full downlink channel information of the terminals 320-1 to 320-K′ in the zone A 210 and the limited downlink channel information of the terminals 320-K′+1 to 320-K in the zone B 220, the base station 310 calculates the precoding vectors and the combining vectors for each terminal as follows. The limited downlink channel information provided to the base station 310 is a principal vector acquired through a Singular Value Decomposition (SVD) of the downlink channel matrix, or a vector index similar to the principal vector amongst beamforming vectors of a codebook. Herein, the principal vector indicates a right singular vector corresponding to the greatest singular value. The terminals 320-K′+1 to 320-K in the zone B 220 performs the SVD on the downlink channel matrix and feeds back the principal vector or the codebook index to the base station 310. When feeding back the codebook index, the terminals 320-K′+1 to 320-K select the vector of the minimum distance to the principal vector. For example, when the codebook in use is a Grassmannian codebook, the terminals 320-K′+1 to 320-K calculate the distance between the vectors based on Equation 2 and select the vector based on Equation 3:

d(mₖ,vₗ^{Q})=sin(θ_{k,l})=\sqrt{1−|mₖ^{H},vₗ^{Q}|²} [Eqn. 2]

In Equation 2, d(mₖ,vₗ^{Q}) denotes a distance between the vector mₖ and the vector vₗ^{Q}.

$${v}_{k}^{Q} = {arg min}_{{v}_{l}^{Q} , l ∈ {N}_{c}} d ( {v}_{k} , {v}_{l}^{Q} ) \qquad [ Eqn . 3 ]$$

In Equation 3, vₖ^{Q} denotes a quantized principal vector of the terminal k, vₖ denotes a principal vector of the terminal k, vₗ^{Q} denotes the l-th vector in the codebook, and N_{c} denotes the number of vectors in the codebook.

Using the downlink channel information of the terminals 320-1 to 320-K′ in the zone A 210 and the information fed back from the terminals 320-K′+1 to 320-K in the zone B 220, the base station 310 calculates downlink precoding vectors for the terminals 320-1 to 320-K to be connected in the spatial multiple access manner. At this time, signal powers to the terminals 320-K′+1 to 320-K in the zone B 220 are uniformly allocated, and signal powers to the terminals 320-1 to 320-K′ in the zone A 210 are allocated based on the channel state. For example, when the total transmit power of the base station is P_{T}, the number of the terminals in the zone A 210 is K′, and the total number of the terminals is K, the total power allocated to the terminals in the zone A 210 is

$$\frac{{K}^{′}}{K} {P}_{T}$$

and the power allocated to the individual terminal in the zone B 220 is

$$\frac{{P}_{T}}{K} .$$

The base station 310 constitutes stack matrixes for each terminal using the collected channel information and the principal vector information, or the channel information and the codebook index information. Herein, the stack matrix indicates a matrix sequentially stacking the downlink effective channel matrixes of the terminals 320-1 to 320-K′ in the zone A 210 and Hermitian matrixes of the principal vector fed back from the terminals 320-K′+1 to 320-K in the zone B 220 or Hermitian matrixes of the beamforming vectors corresponding to the codebook index. The stack matrixes corresponding to the respective terminals differ from each other. For example, when the principal vector is fed back, the stack matrix of the terminal k 320-k is generated using the effective channel matrixes of the other terminals excluding the terminal k 320-k or the Hermitian matrixes of the principal vector, which is expressed as Equation 4:

$${\tilde{H}}_{k} = \{ \begin{matrix}{[ \begin{matrix}{H}_{eff , 1}^{T} , … , {H}_{eff , k - 1}^{T} , \\ {H}_{eff , k + 1}^{T} , … , {H}_{eff , {K}^{′}}^{T} , \\ {( {v}_{{K}^{′} + 1}^{H} )}^{T} , … , {( {v}_{K}^{H} )}^{T}\end{matrix} ]}^{T} , & k ∈ \{ 1 , … , {K}^{′} \} \\ {[ \begin{matrix}{H}_{eff , 1}^{T} , … , {H}_{eff , {K}^{′}}^{T} , \\ {( {v}_{{K}^{′} + 1}^{H} )}^{T} , … , {( {v}_{k - 1}^{H} )}^{T} , \\ {( {v}_{k + 1}^{H} )}^{T} , … , {( {v}_{K}^{H} )}^{T}\end{matrix} ]}^{T} , & k ∈ \{ {K}^{′} + 1 , … \}\end{matrix} \qquad [ Eqn . 4 ]$$

In Equation 4, \tilde{H}ₖ denotes the stack matrix of the terminal k, H_{eff,k}^{T} denotes the effective channel matrix of the terminal k, and vₖ denotes the principal vector of the terminal k. H_{eff,k}^{T} is defined to the product of the Hermitian matrix of the combining vector and the downlink channel matrix of the terminal k 320-k.

From the stack matrix generated based on Equation 4, the precoding vector of the terminal k 320-k is calculated. The precoding vector of the terminal k 320-k is a right singular vector corresponding to a zero singular value among the column vectors among right singular vectors acquired through the SVD of the stack matrix of the terminal k 320-k, which is expressed as Equation 5:

mₖ=NULL{\tilde{H}ₖ} [Eqn. 5]

In Equation 5, mₖ denotes the precoding vector of the terminal k, \tilde{H}ₖ denotes the stack matrix of the terminal k, and NULL{ } denotes a function of selecting the right singular vector corresponding to the zero singular value among the column vectors in the right singular matrix.

The precoding vector of the terminal assigned a single stream is determined to one right singular vector corresponding to the zero singular value. By contrast, the precoding vector of the terminal assigned multiple streams is determined to a matrix including the right singular vectors corresponding to the zero singular values as many as the streams.

Using the precoding vector calculated based on Equation 4 and Equation 5, the downlink signal model received at the individual terminal 320-1 to 320-K is given as Equation 6:

$${r}_{k} = \{ \begin{matrix}{w}_{k}^{H} {H}_{k} {m}_{k} {s}_{k} + {w}_{k}^{H} {n}_{k} , & k ∈ \{ 1 , … , {K}^{′} \} \\ {w}_{k}^{H} {H}_{k} {m}_{k} {s}_{k} + {w}_{k}^{H} {H}_{k} {\sum }_{l = 1 , l \neq k}^{K} {m}_{l} {s}_{l} + {w}_{k}^{H} {n}_{k} , & k ∈ \{ {K}^{′} + 1 , … , K \}\end{matrix} \qquad [ Eqn . 6 ]$$

In Equation 6, rₖ denotes the receive signal model of the terminal k, wₖ denotes the combining vector of the terminal k, Hₖ denotes the channel matrix of the terminal k, mₖ denotes the precoding vector of the terminal k, sₖ denotes the transmit signal of the terminal k, nₖ denotes noise affecting the terminal k, K′ denotes the number of the terminals in the zone A, and K denotes the number of terminals connected in the spatial multiple access manner.

As the terminals 320-1 to 320-K′ traveling in the zone A 210 utilize the accurate channel information, signals to other terminals are eliminated. However, since the terminals 320-K′+1 to 320-K traveling in the zone B 220 utilize merely the principal vector of the channel matrix, signal components to other terminals still remain. Correspondingly, the combining vectors for the terminals 320-1 to 320-K′ in the zone A 210 and the combining vectors for the terminals 320-K′+1 to 320-K in the zone B 220 are determined in different manners. The combining vector of the individual terminal 320-1 to 320-K is calculated based on Equation 7:

$${w}_{k} = \{ \begin{matrix}{LSVD}_{1} \{ {H}_{k} {m}_{k} \} , & k ∈ \{ 1 , … , {K}^{′} \} \\ \frac{{R}_{k}^{- \frac{1}{2}} {H}_{k} {m}_{k}}{{‖ {R}_{k}^{- \frac{1}{2}} {H}_{k} {m}_{k} ‖}_{2}} , & k ∈ \{ {K}^{′} + 1 , … , K \}\end{matrix} \qquad [ Eqn . 7 ]$$

In Equation 7, wₖ denotes the combining vector of the terminal k, Hₖ denotes the channel matrix of the terminal k, mₖ denotes the precoding vector of the terminal k, Rₖ denotes a spatial correlation matrix of interference and noise of the terminal k, K′ denotes the number of the terminals in the zone A, and K denotes the number of terminals connected in the spatial multiple access manner.

As expressed in Equation 7, the combining vector of the terminal in the zone A is determined by performing the SVD on the product of the channel matrix and the precoding vector and then selecting out the column vector corresponding to the principal singular value in the left singular matrix produced through the SVD. The combining vector of the terminal in the zone B is determined by whitening an interference signal in the product of the channel matrix and the precoding vector and then normalizing the magnitude of the whitened vector. Herein, the whitening is a function of making the interference as the noise, which is represented by multiplying by the reciprocal of the spatial correlation matrix Rₖ.

The spatial correlation matrix Rₖ of the interference and the noise used to calculate the combining vector of the terminal in the zone B 220 is expressed as Equation 8 and Equation 9. The spatial correlation matrix Rₖ of the interference and the noise is computed and fed back by the terminal.

Rₖ=E{zₖzₖ^{H}} [Eqn. 8]

In Equation 8, Rₖ denotes the spatial correlation matrix of the interference and the noise of the terminal k, E{ } denotes an average operator, and zₖ denotes an interference and noise matrix.

$${z}_{k} = {H}_{k} {\sum }_{l = 1 , l \neq k}^{K} {m}_{l} {s}_{l} + {n}_{k} \qquad [ Eqn . 9 ]$$

In Equation 9, zₖ denotes the interference and noise matrix, Hₖ denotes the channel matrix of the terminal k, K denotes the number of the terminals connected in the spatial multiple access manner, mₖ denotes the preceding vector of the terminal k, sₖ denotes the transmit signal of the terminal k, and nₖ denotes noise affecting the terminal k.

In the calculation of the precoding vectors and the combining vectors for terminals, the base station 310 initializes the combining vectors of the terminals 310-1 to 320-K′ in the zone A 210 and then calculates the precoding vectors for each terminal through the iterative operation. The initial value of the combining vectors varies in exemplary embodiments of the present invention. For example, the initial value of the combining vectors may be a vector in which one element ‘1’ and the other elements ‘0’, or the left principal singular vector acquired through the SVD of the channel matrix. The base station 310 feeds forward the calculated precoding vectors to the terminals 320-1 to 320-K. The terminals 320-1 to 320-K compute their combining vector based on Equation 7.

As aforementioned, the terminals 320-K′+1 to 320-K in the zone B 220 may feed back the codebook index. In this case, the stack matrix in Equation 4 is substituted by Equation 10:

$${\tilde{H}}_{k} = \{ \begin{matrix}{[ \begin{matrix}{H}_{eff , 1}^{T} , … , {H}_{eff , k - 1}^{T} , {H}_{eff , k + 1}^{T} , … , \\ {H}_{eff , {K}^{′}}^{T} , {( {( {v}_{{K}^{′} + 1}^{Q} )}^{H} )}^{T} , … , {( {( {v}_{K}^{Q} )}^{H} )}^{T}\end{matrix} ]}^{T} , & k ∈ \{ 1 , … , {K}^{′} \} \\ {[ \begin{matrix}{H}_{eff , 1}^{T} , … , {H}_{eff , {K}^{′}}^{T} , {( {( {v}_{{K}^{′} + 1}^{Q} )}^{H} )}^{T} , … , \\ {( {( {v}_{k - 1}^{Q} )}^{H} )}^{T} , {( {( {v}_{k + 1}^{Q} )}^{H} )}^{T} , … , {( {( {v}_{K}^{Q} )}^{H} )}^{T}\end{matrix} ]}^{T} , & k ∈ \{ {K}^{′} + 1 , … \}\end{matrix} \qquad [ Eqn . 10 ]$$

In Equation 10, \tilde{H}ₖ denotes the stack matrix of the terminal k, H_{eff,k}^{T} denotes the effective channel matrix of the terminal k, and vₖ^{Q} denotes the quantized principal vector of the terminal k. H_{eff,k}^{T} is defined to the product of the Hermitian matrix of the combining vector and the downlink channel matrix of the terminal k.

When the precoding vectors and the combining vectors are calculated as above, the sum channel capacity of the system is the summation of the channel capacity of the terminals in the zone A 210 and the channel capacity of the terminals in the zone B 220. Herein, the channel capacity of the terminals in the zone A 210 may be given as Equation 11 and the channel capacity of the terminals in the zone B 220 may be given as Equation 12:

$${C}_{A} = {max}_{{P}_{k} \leq ( \frac{{K}^{′}}{K} ) {P}_{T}} {log}_{2} det ( I + \frac{1}{{σ}_{n}^{2}} {w}_{k}^{H} {H}_{k} {m}_{k} {Pm}_{k}^{H} {H}_{k}^{H} {w}_{k} ) \qquad [ Eqn . 11 ]$$

In Equation 11, C_{A} denotes the channel capacity of the terminals in the zone A, Pₖ denotes the transmit power allocated to the terminal k, P_{T} denotes the total transmit power of the base station, K′ denotes the number of the terminals in the zone A, K denotes the number of terminals connected in the spatial multiple access manner, det( ) is a determinant operator, wₖ denotes the combining vector of the terminal k, Hₖ denotes the channel matrix of the terminal k, mₖ denotes the precoding vector of the terminal k, and σₙ² denotes the noise power.

$${C}_{B} = {\sum }_{k = {K}^{′} + 1}^{K} {log}_{2} det ( 1 + \frac{{P}_{T}}{K} {w}_{k}^{H} {H}_{k} {m}_{k} {m}_{k}^{H} {H}_{k}^{H} {{w}_{k} ( {w}_{k}^{H} {R}_{k} {w}_{k} )}^{- 1} ) \qquad [ Eqn . 12 ]$$

In Equation 12, C_{B} denotes the channel capacity of the terminals in the zone B, P_{T} denotes the total transmit power of the base station, K′ denotes the number of the terminals in the zone A, K denotes the number of terminals connected in the spatial multiple access manner, det( ) is the determinant operator, wₖ denotes the combining vector of the terminal k, Hₖ denotes the channel matrix of the terminal k, mₖ denotes the precoding vector of the terminal k, and Rₖ denotes the spatial correlation matrix of the interference and the noise of the terminal k.

Now, structures of the base station and the terminal for the beamforming are described in detail by referring to the drawings.

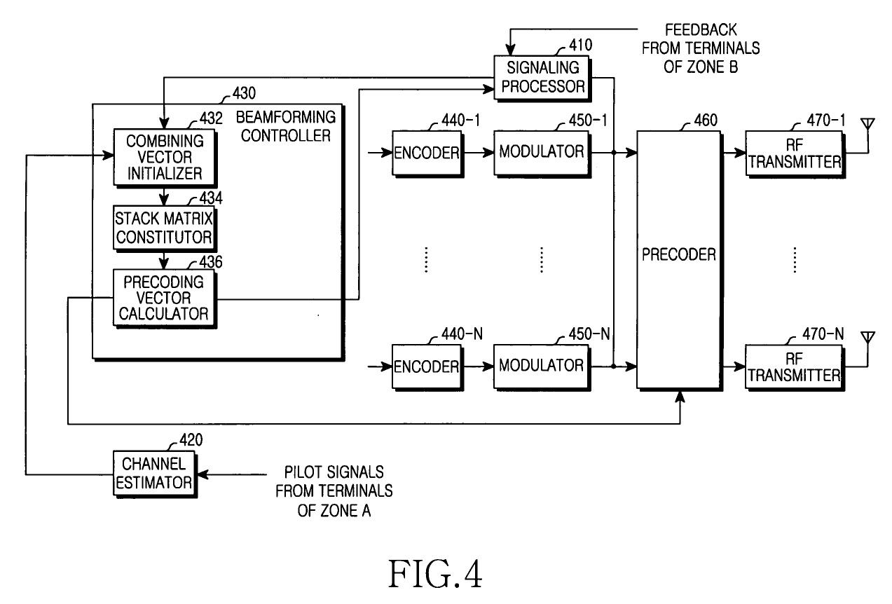

FIG. 4 is a block diagram of the base station in the MIMO wireless communication system according to an exemplary embodiment of the present invention.

The base station of FIG. 4 includes a signaling processor 410, a channel estimator 420, a beamforming controller 430, a plurality of encoders 440-1 to 440-N, a plurality of modulators 450-1 to 450-N, a precoder 460, and a plurality of Radio Frequency (RF) transmitters 470-1 to 470-N.

The signaling processor 410 confirms information contained in a control signal by analyzing the control signal received from the terminal, and generates a control signal including control information to be provided to the terminals. In particular, the signaling processor 410 confirms the principal vector information of the channel matrix fed back from the terminal of the zone B. The principal vector information is the principal vector value, or the codebook index indicative of the vector most similar to the principal vector in the codebook. When the principal vector value is fed back, the signaling processor 410 provides the principal vector value to the beamforming controller 430. When the codebook index is fed back, the signaling processor 410 retrieves the vector corresponding to the index in the codebook and provides the retrieved vector value to the beamforming controller 430. Herein, the codebook may be one of a Grassmannian quantization codebook, a random codebook and a Lloyd quantization codebook. The signaling processor 410 generates a control signal including information of the precoding vectors of the terminals determined at a precoding vector calculator 436.

The channel estimator 420 estimates the channel matrix of the terminals of the zone A using signals received in the uplink channel. For example, the channel estimator 420 estimates the channel matrix of the terminals using pilot signals or sounding signals received from the terminals. Next, the channel estimator 420 provides the channel matrix information to the beamforming controller 430.

The beamforming controller 430 determines the precoding vectors and the combining vectors of the terminals to be connected in the spatial multiple access manner. The beamforming controller 430 produces optimum precoding vectors and optimum combining vectors by repeatedly computing the precoding vectors and the combining vectors and generating the stack matrix for the computed combining vectors. The beamforming controller 430 includes a combining vector initializer 432, a stack matrix constitutor 434, and the precoding vector calculator 436.

The combining vector initializer 432 initializes the combining vectors of the terminals in the zone A for the stack matrix generation prior to the iterative operation. The initial value of the combining vector depends on exemplary embodiments of the present invention. For example, the initial value of the combining vectors may be a vector in which one element ‘1’ and the other elements ‘0’, or the left principal singular vector acquired through the SVD of the channel matrix. Using the left principal singular vector, the combining vector initializer 432 applies the SVD to the channel matrix of the terminals in the zone A estimated by the channel estimator 420, and sets the left principal singular vectors to the initial value of the combining vectors.

The stack matrix constitutor 434 constitutes the stack matrixes of the terminals to be connected in the spatial multiple access manner, using the combining vector initial values of the terminals of the zone A provided from the combining vector initializer 432, the channel matrixes of the terminals in the zone A estimated by the channel estimator 420, and the principal vectors of the channel matrix of the terminals in the zone B provided from the signaling processor 410. When the principal vector information fed back from the terminals of the zone B is the principal vector value, the stack matrix constitutor 434 constitutes the stack matrix of the corresponding terminal based on Equation 4 by sequentially stacking the products of the Hermitian matrix of the combining vector and the channel matrix or the Hermitian matrixes of the principal vectors of the other terminals than the corresponding terminal. In contrast, when the principal vector information fed back from the terminals in the zone B is the codebook index, the stack matrix constitutor 434 constitutes the stack matrix of the corresponding terminal based on Equation 10 by sequentially stacking the products of the Hermitian matrix of the combining vector and the channel matrix or the Hermitian matrixes of the vectors corresponding to the codebook index of the other terminals excluding the corresponding terminal.

The precoding vector calculator 436 determines the precoding vectors of the terminals using the stack matrixes of the terminals constituted at the stack matrix constitutor 434. To do so, the precoding vector calculator 436 performs the SVD on the stack matrix of the corresponding terminal, selects out the right singular vector corresponding to the zero singular value among the column vectors in the right singular matrix acquired through the SVD, and thus acquires the precoding vector of the corresponding terminal.

The encoders 440-1 to 440-N encode data to be transmitted in the respective streams. The modulators 450-1 to 450-N modulate the encoded data to be transmitted in the respective streams and converts to complex symbols. The precoder 460 processes the signals to be transmitted in the respective streams according to the precoding vectors provided from the beamforming controller 430. More specifically, the precoder 460 multiplies the transmit signals of the terminals by the precoding vectors of the terminals and sums up the signals multiplied by the preceding vectors. The RF transmitters 470-1 to 470-N convert the per-antenna signals output from the precoder 460 to RF signals and transmit the RF signals over a plurality of transmit antennas.

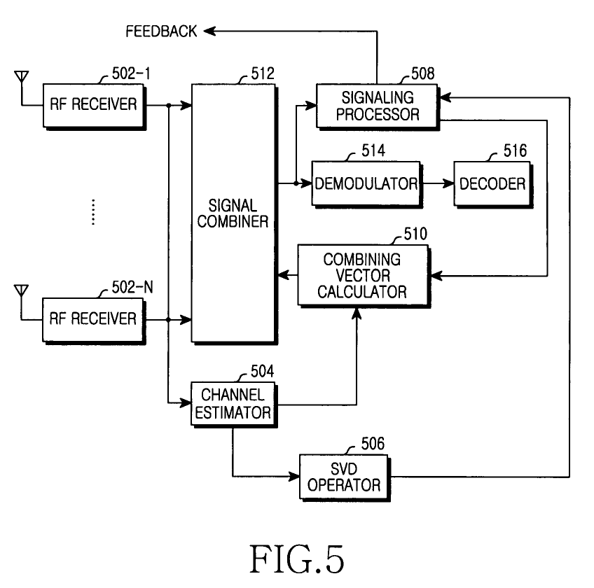

FIG. 5 is a block diagram of the terminal in the MIMO wireless communication system according to an exemplary embodiment of the present invention.

The terminal of FIG. 5 includes a plurality of RF receivers 502-1 to 502-N, a channel estimator 504, a Singular Value Decomposition (SVD) operator 506, a signaling processor 508, a combining vector calculator 510, a signal combiner 512, a demodulator 514, and a decoder 516.

The RF receivers 502-1 to 502-N convert RF signals received via a plurality of receive antennas to baseband signals and provides the baseband signals to the signal combiner 512. The channel estimator 504 estimates a downlink channel matrix using a pilot signal or a preamble signal received from the base station. The SVD operator 506 performs the SVD on the channel matrix estimated by the channel estimator 504. The SVD operator 506 provides the principal vector value acquired through the SVD to the signaling processor 508.

The signaling processor 508 generates a control signal including control information to be provided to the base station and analyzes a control signal received from the base station. In particular, when the terminal is in the zone B, the signaling processor 508 generates the control signal including the principal vector information. The principal vector information may be the principal vector value or the index of the vector most similar to the principal vector in the codebook. Herein, the codebook may be a Grassmannian quantization codebook, a random codebook, or a Lloyd quantization codebook. When the principal vector information is the codebook index, the signaling processor 508 selects a vector most similar to the principal vector in the vectors of the codebook and generates the control signal including the index of the selected vector. In addition, the signaling processor 508 confirms the precoding vector information of the terminal in the control signal received from the base station, and provides the precoding vector information to the combining vector calculator 510. Notably, when the terminal is in the zone A, the signaling processor 508 does not generate the control signal including the principal vector information.

The combining vector calculator 510 determines the combining vector using the precoding vector and the channel matrix. The combining vector calculation of the combining vector calculator 510 differs depending on the location of the terminal. When the terminal is in the zone A, the combining vector calculator 510 performs the SVD on the product of the channel matrix of the preceding vector, selects out the column vector corresponding to the principal singular value in the left singular matrix acquired through the SVD, and thus determines the combining vector. When the terminal is in the zone B, the combining vector calculator 510 determines the spatial correlation matrix of the interference and the noise using the channel matrix and the interference signals. That is, the combining vector calculator 510 sums up the interference signals and the noise received over the channel. Next, the combining vector calculator 510 produces the spatial correlation matrix of the interference and the noise by averaging the elements of the matrix obtained by multiplying the summation by the Hermitian matrix of the summation, which is expressed as Equation 8 and Equation 9. Next, the combining vector calculator 510 divides the product of the reciprocal of the square root of the spatial correlation matrix of the interference and the noise, the channel matrix, and the precoding vector, by 2 norms of the product of the reciprocal of the square root of the spatial correlation matrix of the interference and the noise, the channel matrix, and the precoding vector, and thus determines the combining vector of the corresponding terminal, which is expressed as Equation 7.

The signal combiner 512 processes the receive signals using the combining vector calculated at the combining vector calculator 510. In more detail, the signal combiner 512 multiplies the signals received over the receive antennas by the Hermitian matrix of the combining vector and thus extracts the signal transmitted in its assigned stream. The demodulator 514 converts to a bit stream by demodulating the complex symbols output from the signal combiner 512. The decoder 516 decodes the bit stream output from the demodulator 514.

Hereafter, the operations of the base station and the terminal for the beamforming are explained in detail by referring to the drawings.

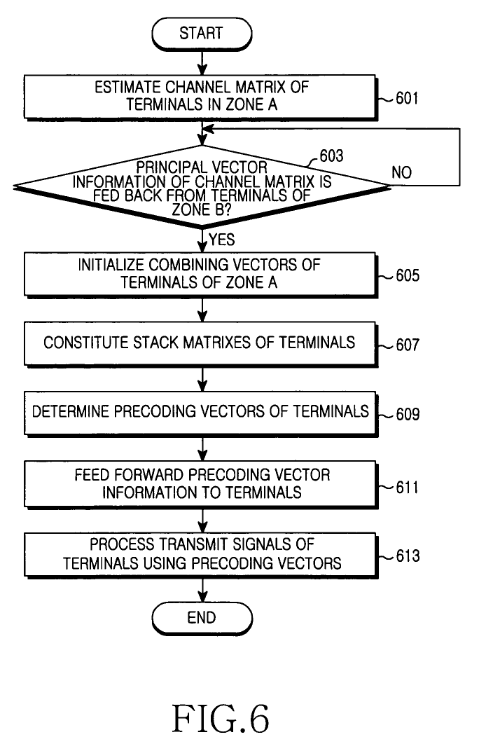

FIG. 6 is a flowchart outlining the operations of the base station in the MIMO wireless communication system according to an exemplary embodiment of the present invention.

In step 601, the base station estimates the channel matrix of the terminals traveling in the zone A. That is, the base station estimates the channel matrix of the terminals which use the same band in the uplink communication and in the downlink communication. For example, the base station estimates the channel matrix of the terminals using the sounding signals received from the terminals.

In step 603, the base station checks whether the principal vector information of the channel matrix is fed back from the terminals of the zone B. In other words, the base station checks whether the principal vector information of the downlink channel matrix is fed back from the terminals which use the different bands in the uplink communication and in the downlink communication. Herein, the principal vector information may be the principal vector value, or the index of the vector most similar to the principal vector in the codebook. The codebook may be a Grassmannian quantization codebook, a random codebook, or a Lloyd quantization codebook.

When the principal vector information of the channel matrix is fed back from the terminals of the zone B, the base station initializes the combining vectors of the terminals of the zone A in step 605. The initial value of the combining vectors varies in the embodiments of the present invention. For example, the initial value of the combining vectors may be a vector in which one element ‘1’ and the other elements ‘0’, or the left principal singular vector acquired through the SVD of the channel matrix.

In step 607, the base station constitutes the stack matrix of each terminal. In further detail, the base station constitutes the stack matrixes of the terminals to be connected in the spatial multiple access manner, using the combining vector initial values of the terminals of the zone A, the channel matrixes of the terminals of the zone A, and the principal vectors of the channel matrix of the terminals of the zone B. When the principal vector information fed back from the terminals of the zone B is the principal vector value, the base station constitutes the stack matrix of the corresponding terminal based on Equation 4 by sequentially stacking the products of the Hermitian matrix of the combining vector and the channel matrix or the Hermitian matrixes of the principal vectors of the other terminals than the corresponding terminal. In contrast, when the principal vector information fed back from the terminals in the zone B is the codebook index, the base station constitutes the stack matrix of the corresponding terminal based on Equation 10 by sequentially stacking the products of the Hermitian matrix of the combining vector and the channel matrix or the Hermitian matrixes of the vectors corresponding to the codebook index of the other terminals than the corresponding terminal.

In step 609, the base station determines the precoding vector of each terminal using the stack matrix of each terminal. To do so, the base station performs the SVD on the stack matrix of the corresponding terminal, selects out the right singular vector corresponding to the zero singular value among the column vectors in the right singular matrix acquired through the SVD, and thus determines the precoding vector of the corresponding terminal.

In step 611, the base station feeds forward the preceding vector information to the terminals.

In step 613, the base station processes the transmit signals destined for the terminals using the precoding vectors. In more detail, the base station multiplies the transmit signals of the terminals by the preceding vectors of the terminals respectively and sums up the signals multiplied by the preceding vectors. The base station converts the precoded signals to RF signals and transmits the RF signals over the plurality of the transmit antennas.

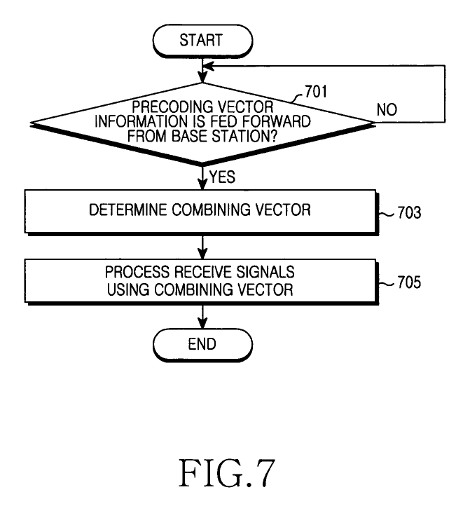

FIG. 7 is a flowchart outlining the operations of the terminal in the zone A in the MIMO wireless communication system according to an exemplary embodiment of the present invention. FIG. 7 illustrates the operations of the terminal using the same band in the uplink communication and in the downlink communication; that is, the terminal compliant with the TDD scheme.

In step 701, the terminal checks whether the preceding vector information is fed forward from the base station or not.

When the combining vector information is fed forward, the terminal determines the combining vector using the precoding vector and the channel matrix in step 703. In more detail, the terminal performs the SVD on the product of the channel matrix and the precoding vector, retrieves the column vector corresponding to the principal singular value in the left singular matrix acquired through the SVD, and thus determines the combining vector, which is expressed as Equation 7.

In step 705, the terminal processes the receive signals using the combining vector calculated in step 703. That is, the terminal extracts the signal transmitted in its allocated stream by multiplying the signals received over the receive antennas by the Hermitian matrix of the combining vector.

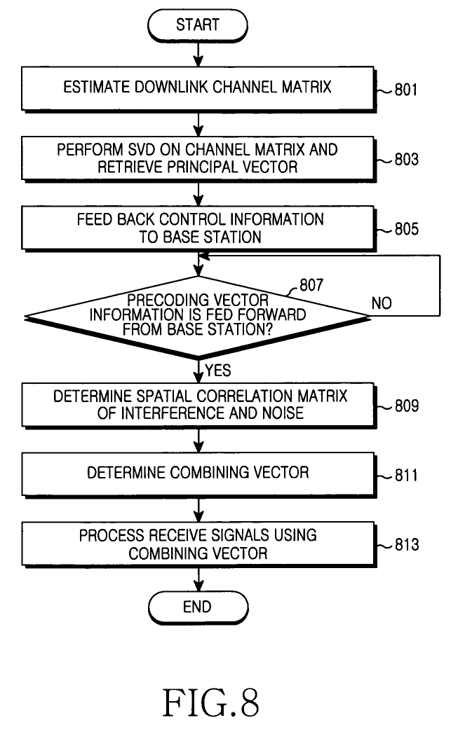

FIG. 8 is a flowchart outlining the operations of the terminal in the zone B in the MIMO wireless communication system according to an exemplary embodiment of the present invention. FIG. 8 illustrates the operations of the terminal using the different bands in the uplink communication and in the downlink communication; that is, the terminal compliant with the FDD scheme.

In step 801, the terminal estimates the downlink channel matrix. The terminal estimates the downlink channel matrix using the pilot signal or the preamble signal received from the base station.

In step 803, the terminal performs the SVD on the channel matrix and retrieves the right singular vector corresponding to the maximum singular value; that is, the principal vector.

In step 805, the terminal feeds back the principal vector information calculated in step 803 to the base station. The principal vector information may be the principal vector value, or the codebook index indicative of the vector most similar to the principal vector in the codebook. Herein, the codebook may be a Grassmannian quantization codebook, a random codebook, or a Lloyd quantization codebook.

In step 807, the terminal checks whether the precoding vector information is fed and forwarded from the base station.

When the precoding vector information is fed forward, the terminal calculates the spatial correlation matrix of the interference and the noise using the channel matrix and the interference signals in step 809. That is, the terminal sums up the interference signals and the noise received over the channel. Next, the terminal normalizes all the elements of the matrix produced by multiplying the summation by the Hermitian matrix of the summation and thus obtains the spatial correlation matrix of the interference and the noise, which are expressed as Equation 8 and Equation 9.

In step 811, the terminal determines the combining vector using the precoding vector, the channel matrix, and the spatial correlation matrix of the interference and the noise. In more detail, the terminal determines the combining vector of the corresponding terminal by dividing the product of the reciprocal of the square root of the spatial correlation matrix of the interference and the noise, the channel matrix, and the precoding vector, by the 2 norms of the product of the reciprocal of the spatial correlation matrix of the interference and the noise, the channel matrix, and the precoding vector, which is expressed as Equation 7.

In step 813, the terminal processes the receive signals using the combining vector calculated in step 811. That is, the terminal extracts the signal transmitted in its allocated stream by multiplying the signals received over the receive antennas by the Hermitian matrix of the combining vector.

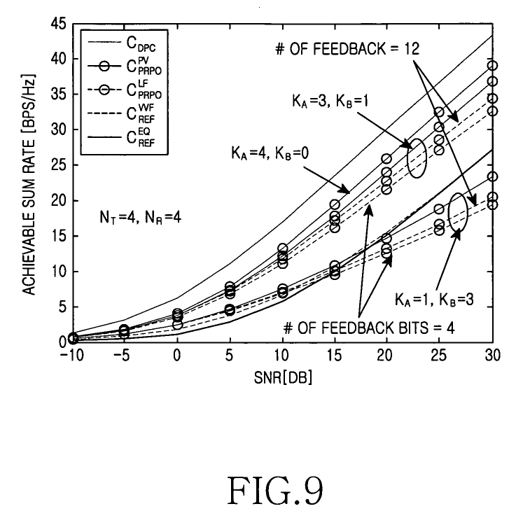

FIG. 9 is a graph of a performance of the MIMO wireless communication system according to an exemplary embodiment of the present invention. In particular, FIG. 9 shows simulation results for measuring a sum rate based on a Signal to Noise Ratio (SNR) of the present system and the conventional systems. In the simulation, it is assumed that the number of the transmit antennas of the bases station is 4 and the number of the receive antennas of the terminal is 4.

In FIG. 9, Cₚᵣₒₚ indicates the channel capacity of the present system, C_{DPC} indicates the channel capacity of the system using a Dirty Paper Coding (DPC) for an optimum channel capacity, and C_{ref} indicates the channel capacity of the system which rejects interference between users using an Orthogonal Frequency Division Multiplexing (OFDM) system or a Time Division Multiple Access (TDMA) system without using the spatial diversity between the users. PV implies that the terminals in the zone B feedback the principal vector, LF implies that the terminals in the zone B feedback the codebook index, WF implies that a water-filling power allocation is adopted, and EQ implies that an equal power allocation is adopted.

When the user of the zone B feeds back the principal vector as the feedback information, Cₚᵣₒₚ approaches C_{DPC} as the SNR increases. There is a gap between C_{DPC} and Cₚᵣₒₚ because the DPC regulates the number of the transmit streams per user according to the mode selection based on the channel condition and every terminal of the present system transmits only the same stream alone. When the codebook index is fed back, the channel capacity decreases as the number of the users in the zone B increases. At the low SNRs, the channel capacity increases by virtue of the antenna diversity, compared to the user interference rejection using the OFDM or the TDMA.

As set forth above, the precoding vectors and the combining vectors are generated using the full channel information of the terminal compliant with the TDD and the limited channel information of the terminal compliant with the FDD in the MIMO wireless communication system. Therefore, when the HDD is adopted, the system performance may be enhanced through the spatial multiple division.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. An apparatus for a base station in a Multiple Input Multiple Output (MIMO) wireless communication system, the apparatus comprising:
an estimator for estimating a channel matrix of at least one terminal compliant with a Time Division Duplex (TDD) scheme;
a processor for confirming information indicative of a channel matrix fed back from at least one terminal compliant with a Frequency Division Duplex (FDD) scheme; and
a controller for determining precoding vectors for terminals to be connected in a spatial multiple access manner, using the channel matrix of the at least one terminal compliant with the TDD scheme and a principal vector of the at least one terminal compliant with the FDD scheme.

2. The apparatus of claim 1, wherein the information indicative of the channel matrix comprises a principal vector corresponding to a maximum value among singular values acquired through a Singular Value Decomposition (SVD) of the channel matrix.

3. The apparatus of claim 2, wherein the information indicative of the principal vector comprises a codebook index,
the processor confirms a vector corresponding to the codebook index in a codebook, and
the controller uses the vector corresponding to the codebook index as the principal vector.

4. The apparatus of claim 3, wherein the controller comprises:
an initializer for initializing a combining vector of the at least one terminal compliant with the TDD scheme;
a constitutor for determining stack matrixes of the terminals to be connected in the spatial multiple access manner, using the channel matrix of the at least one terminal compliant with the TDD scheme, the combining vector of the at least one terminal compliant with the TDD scheme, and the principal vector of the at least one terminal compliant with the FDD scheme; and
a calculator for determining the precoding vectors of the terminals by determining a right singular vector corresponding to a zero singular value of the stack matrix of the individual terminal.

5. The apparatus of claim 4, wherein the initializer initializes the combining vector with one of a left principal singular vector acquired through the SVD of the channel matrix of the at least one terminal compliant with the TDD scheme, and a vector comprising one ‘1’ and at least one ‘0’.

6. The apparatus of claim 5, wherein the constitutor determines a stack matrix of a corresponding terminal by sequentially stacking products of a Hermitian matrix of the combining vector and the channel matrix or Hermitian matrixes of the principal vectors of at least one terminal excluding the corresponding terminal.

7. The apparatus of claim 1, further comprising:
a processor for generating a control signal to feed forward information of the preceding vectors calculated by the controller; and
a transmitter for transmitting the control signal to each terminal.

8. An apparatus for a terminal in a Multiple Input Multiple Output (MIMO) wireless communication system, the apparatus comprising:
a processor for confirming precoding vector information from a control signal received from a base station;
a calculator for determining a combining vector using the preceding vector; and
a combiner for extracting a signal transmitted in at least one allocated stream, by multiplying signals received via a plurality of receive antennas by a Hermitian matrix of the combining vector.

9. The apparatus of claim 8, wherein the calculator determines the combining vector by performing a singular value decomposition on a product of a channel matrix and the precoding vector and retrieving a column vector corresponding to a principal singular value in a left singular matrix acquired through the singular value decomposition.

10. The apparatus of claim 8, wherein the calculator determines the combining vector by whitening an interference signal in the product of the channel matrix and the precoding vector and normalizing a magnitude of the whitened vector.

11. The apparatus of claim 10, wherein the calculator determines the combining vector by summing up interference signals and noise received, calculating a spatial correlation matrix of the interference and the noise by averaging elements produced by multiplying the summation by a Hermitian matrix of the summation, and dividing a product of a reciprocal of a square root of the spatial correlation matrix of the interference and the noise, the channel matrix, and the precoding vector, by 2 norms of the product of the reciprocal of the square root of the spatial correlation matrix of the interference and the noise, the channel matrix, and the precoding vector.

12. The apparatus of claim 8, further comprising:
an estimator for estimating a downlink channel matrix; and
an operator for performing the Singular Value Decomposition (SVD) on the channel matrix and outputting a principal vector value,
wherein the processor generates a control signal comprising information indicative of the principal vector.

13. A method of operating a base station in a Multiple Input Multiple Output (MIMO) wireless communication system, the method comprising:
estimating a channel matrix of at least one terminal compliant with a Time Division Duplex (TDD) scheme;
confirming information indicative of a channel matrix fed back from at least one terminal compliant with a Frequency Division Duplex (FDD) scheme; and
determining preceding vectors for terminals to be connected in a spatial multiple access manner, using the channel matrix of the at least one terminal compliant with the TDD scheme and a principal vector of the at least one terminal compliant with the FDD scheme.

14. The method of claim 13, wherein the information indicative of the channel matrix comprises a principal vector corresponding to a maximum value among singular values acquired through a Singular Value Decomposition (SVD) of the channel matrix.

15. The method of claim 14, wherein the information indicative of the principal vector comprises a codebook index, and the calculating of the preceding vectors comprises using a vector corresponding to the codebook index as the principal vector.

16. The method of claim 15, wherein the determining the precoding vectors comprises:
initializing a combining vector of the at least one terminal compliant with the TDD scheme;
determining stack matrixes of the terminals to be connected in the spatial multiple access manner, using the channel matrix of the at least one terminal compliant with the TDD scheme, the combining vector of the at least one terminal compliant with the TDD scheme, and the principal vector of the at least one terminal compliant with the FDD scheme; and
determining the precoding vectors of the terminals by calculating a right singular vector corresponding to a zero singular value of the stack matrix of the individual terminal.

17. The method of claim 16, wherein an initial value of the combining vector is one of a left principal singular vector acquired through the SVD of the channel matrix of the at least one terminal compliant with the TDD scheme and a vector comprising one ‘1’ and at least one ‘0’.

18. The method of claim 17, wherein a stack matrix is determined by sequentially stacking products of a Hermitian matrix of the combining vector and the channel matrix or Hermitian matrixes of the principal vectors of at least one terminal excluding the corresponding terminal.

19. The method of claim 13, further comprising:
feeding forward information of the precoding vector calculated by the controller.

20. A method for operating a terminal in a Multiple Input Multiple Output (MIMO) wireless communication system, the method comprising:
confirming precoding vector information from a control signal received from a base station;
determining a combining vector using the precoding vector; and
extracting a signal transmitted in at least one allocated stream, by multiplying signals received via a plurality of receive antennas by a Hermitian matrix of the combining vector.

21. The method of claim 20, wherein the combining vector is determined by performing a singular value decomposition on a product of a channel matrix and the precoding vector and retrieving a column vector corresponding to a principal singular value in a left singular matrix acquired through the singular value decomposition.

22. The method of claim 20, wherein the combining vector is determined by whitening an interference signal in the product of the channel matrix and the precoding vector and normalizing a magnitude of the whitened vector.

23. The method of claim 22, wherein the combining vector is determined by summing up interference signals and noise received, calculating a spatial correlation matrix of the interference and the noise by averaging elements produced by multiplying the summation by a Hermitian matrix of the summation, and dividing a product of a reciprocal of a square root of the spatial correlation matrix of the interference and the noise, the channel matrix, and the precoding vector, by 2 norms of the product of the reciprocal of the square root of the spatial correlation matrix of the interference and the noise, the channel matrix, and the precoding vector.

24. The method of claim 20, further comprising:
estimating a downlink channel matrix; and
performing the Singular Value Decomposition (SVD) on the channel matrix and feeding back a principal vector value.
